(19) United States
(12) Patent Application Publication
(10) Pub. No.: US 2018/0329553 A1
(43) Pub. Date: Nov. 15, 2018

(54) IN-CELL TOUCH PANEL

(71) Applicant: Raydium Semiconductor Corporation, Hsinchu (TW)

(72) Inventors: Chang-Ching CHIANG, Taichung City (TW); Kun-Pei LEE, Miaoli County (TW)

(21) Appl. No.: 15/977,032

(22) Filed: May 11, 2018

Related U.S. Application Data
(60) Provisional application No. 62/506,043, filed on May 15, 2017.

(51) Int. Cl. G06F 3/041; H01L 27/32; H01L 51/52; G06F 3/044

(52) U.S. Cl. CPC G06F 3/0412; H01L 27/323; H01L 51/5281; G06F 2203/04112; G06F 3/044; G06F 2203/04111; H01L 27/322

(57) ABSTRACT

An in-cell touch panel is disclosed. The in-cell touch panel includes a plurality of pixels. A laminated structure of each pixel includes a substrate, an encapsulation layer, an organic emissive layer, a first conductive layer and a second conductive layer. The encapsulation layer is disposed opposite to the substrate. The organic emissive layer is formed between the substrate and the encapsulation layer. The first conductive layer is formed between the organic emissive layer and the encapsulation layer. The second conductive layer is formed between the organic emissive layer and the encapsulation layer.

### BACKGROUND OF THE INVENTION

### 1. Field of the Invention

The invention relates to a touch panel; in particular, to an in-cell touch panel.

### 2. Description of the Prior Art

In general, capacitive touch panels using active matrix organic light emitting diode (AMOLED) display technology can be divided into different types based on their different laminated structures, such as in-cell AMOLED capacitive touch panels having the touch sensing electrode disposed under the encapsulation layer and on-cell AMOLED capacitive touch panels having the touch sensing electrode disposed above the encapsulation layer.

Compared to the conventional one glass solution (OGS) AMOLED capacitive touch panel and the on-cell AMOLED capacitive touch panel, the in-cell AMOLED capacitive touch panel can achieve the thinnest AMOLED touch panel design and it can be widely used in portable electronic products such as cell phones, tablet PCs and notebook PCs.

However, the RC loading of the current in-cell touch panel will be largely increased due to the larger parasitic capacitance and the noise interference between the touch mode and the display mode; therefore, the touch performance of the in-cell touch panel will also become poor. The above-mentioned problems should be overcome.

### SUMMARY OF THE INVENTION

Therefore, the invention provides an in-cell touch panel having novel layout to simplify the design of circuit traces and reduce the effects of resistance and parasitic capacitance to solve the above-mentioned problems and enhance the entire performance of the in-cell touch panel.

An embodiment of the invention is an in-cell touch panel. In this embodiment, the in-cell touch panel includes a plurality of pixels. A laminated structure of each pixel includes a substrate, an encapsulation layer, an organic emissive layer, a first conductive layer and a second conductive layer. The encapsulation layer is disposed opposite to the substrate. The organic emissive layer is formed between the substrate and the encapsulation layer. The first conductive layer is formed between the organic emissive layer and the encapsulation layer. The second conductive layer is formed between the organic emissive layer and the encapsulation layer.

In an embodiment, the in-cell touch panel is an in-cell self-capacitive touch panel or an in-cell mutual-capacitive touch panel.

In an embodiment, the first conductive layer is used as touch electrode traces and the second conductive layer is used as touch electrodes.

In an embodiment, the first conductive layer and the second conductive layer are coupled.

In an embodiment, the laminated structure further includes an insulation layer disposed between the first conductive layer and the second conductive layer, wherein the first conductive layer and the second conductive layer are coupled through a via formed in the insulation layer.

In an embodiment, the first conductive layer and the second conductive layer are coupled in a directly contacting way.

In an embodiment, the first conductive layer and the second conductive layer are electrically insulated.

In an embodiment, the first conductive layer is disposed between the second conductive layer and the encapsulation layer.

In an embodiment, the second conductive layer is disposed between the first conductive layer and the encapsulation layer.

In an embodiment, the second conductive layer is formed by transparent conductive material.

In an embodiment, the laminated structure further includes a third conductive layer formed on the organic emissive layer and used as an anode or a cathode of the organic emissive layer.

In an embodiment, the laminated structure further includes a spacer and a third conductive layer. The spacer is formed on the organic emissive layer. The third conductive layer is formed on the spacer and the organic emissive layer and used as an anode or a cathode of the organic emissive layer.

In an embodiment, at least a part of the second conductive layer used as touch electrode is not formed above the spacer.

In an embodiment, at least a part of the first conductive layer used as touch electrode trace is not formed above the spacer.

In an embodiment, a part of the third conductive layer formed above the spacer, separated from another part of the third conductive layer used as the anode or the cathode of the organic emissive layer, is maintained in a floating state.

In an embodiment, the laminated structure further includes an anti-reflection layer, formed above the encapsulation layer, for eliminating reflected light.

In an embodiment, the anti-reflection layer is a combination of linear polarizer and circular polarizer.

In an embodiment, the anti-reflection layer has a multilayer film structure forming destructive interference to ambient light.

In an embodiment, the first conductive layer is formed in mesh type or along a single direction in an active area of the in-cell touch panel.

In an embodiment, when the organic emissive layer emits a white light, the in-cell touch panel further includes a color filter layer formed above the organic emissive layer and used for filtering the white light.

Compared to the prior art, the in-cell touch panel of the invention has the following advantages and effects:

(1) The designs of touch sensing electrodes and their traces are simple.

(2) The original aspect ratio of the in-cell touch panel is not affected by the layout of the invention.

(3) The RC loading of the touch sensing electrodes can be effectively reduced.

(4) The noise interference between touching and displaying can be effectively reduced.

(5) The module thickness of the AMOLED touch panel can be effectively reduced.

The advantage and spirit of the invention may be understood by the following detailed descriptions together with the appended drawings.

### BRIEF DESCRIPTION OF THE APPENDED DRAWINGS

FIG. 1 illustrates a schematic diagram of the laminated structure of the in-cell touch panel in the first embodiment of the invention.

FIG. 2 illustrates a schematic diagram of the laminated structure of the in-cell touch panel in the second embodiment of the invention.

FIG. 3 illustrates a schematic diagram of the laminated structure of the in-cell touch panel in the third embodiment of the invention.

FIG. 4 illustrates a schematic diagram of the laminated structure of the in-cell touch panel in the fourth embodiment of the invention.

FIG. 5 and FIG. 6 illustrate different layout of traces in the in-cell touch panel of the invention respectively.

FIG. 7 illustrates a schematic diagram of the laminated structure of the in-cell touch panel in the fifth embodiment of the invention.

FIG. 8 illustrates a schematic diagram of the laminated structure of the in-cell touch panel in the sixth embodiment of the invention.

FIG. 9 and FIG. 10 illustrate different layout of traces in the in-cell touch panel of the invention respectively.

FIG. 11 illustrates a schematic diagram of the laminated structure of the in-cell touch panel in the seventh embodiment of the invention.

FIG. 12 illustrates a schematic diagram of the anti-reflection layer being a combination of linear polarizer and circular polarizer.

FIG. 13 illustrates a schematic diagram of the anti-reflection layer having a multilayer film structure forming destructive interference to ambient light.

### DETAILED DESCRIPTION OF THE INVENTION

The invention discloses an in-cell touch panel. In practical applications, the in-cell touch panel of the invention can be an in-cell self-capacitive touch panel or an on-cell self-capacitive touch panel without any specific limitations. The in-cell touch panel includes a plurality of pixels. The actual design of the in-cell touch panel can be designed in different ways based on different panels and characteristics. For example, the invention can be practiced in the in-cell touch panels having the laminated structure including white-light OLED and color filtering layer or other laminated structures without any specific limitations.

In this embodiment, the in-cell touch panel includes a plurality of pixels. A laminated structure of each pixel includes a substrate, an encapsulation layer, an organic emissive layer, a first conductive layer and a second conductive layer. The encapsulation layer is disposed opposite to the substrate. The organic emissive layer is formed between the substrate and the encapsulation layer. The first conductive layer is formed between the organic emissive layer and the encapsulation layer. The second conductive layer is formed between the organic emissive layer and the encapsulation layer. The organic emissive layer can include active matrix organic light emitting diode (AMOLED), but not limited to this.

It should be noticed that, in the invention, the first conductive layer can be formed in mesh type or only along a single direction in an active area of the in-cell touch panel to be used as touch sensing electrode traces; the second conductive layer can be formed by transparent conductive layer and used as touch sensing electrodes. The first conductive layer and the second conductive layer can be coupled or electrically insulated. The first conductive layer can be formed between the second conductive layer and the encapsulation layer or the second conductive layer can be formed between the first conductive layer and the encapsulation layer. That is to say, the first conductive layer can be formed after the second conductive layer or the first conductive layer can be formed before the second conductive layer. In practical applications, multi-functional electrodes can be disposed between the touch sensing electrodes formed by the second conductive layer based on practical needs, but not limited to this.

At first, please refer to FIG. 1. FIG. 1 illustrates a schematic diagram of the laminated structure of the in-cell touch panel in the first embodiment.

As shown in FIG. 1, the laminated structure 1 of the in-cell touch panel can include a substrate SUB, an active layer AL, an isolation layer ISO, a gate electrode G, a source electrode S, a drain electrode D, an anode layer AND, an organic light emitting OEL, a cathode layer CAD, a first conductive layer TR, an insulation layer INS, a via VIA, a second conductive layer TE, an encapsulation layer ENL and an anti-reflection layer ARL. Wherein, the organic light emitting layer OEL is disposed above the substrate SUB. The encapsulation layer ENL, opposite to the substrate SUB, is disposed above the organic light emitting layer OEL. The anti-reflection layer ARL is disposed above the encapsulation layer ENL. The anode layer AND and the cathode layer CAD are disposed under and above the organic light emitting OEL respectively and used as the anode and the cathode of the organic light emitting OEL respectively.

It should be noticed that the first conductive layer TR is disposed on the lower surface of the encapsulation layer ENL and used as the touch sensing electrode traces of the in-cell touch panel. The second conductive layer TE is disposed under the first conductive layer TR and used as the touch sensing electrodes of the in-cell touch panel. As shown in the left part of FIG. 1, the first conductive layer TR and the second conductive layer TE are electrically insulated through the insulation layer INS disposed between them. As shown in the right part of FIG. 1, the first conductive layer TR and the second conductive layer TE are coupled through the via VIA formed in the insulation layer INS.

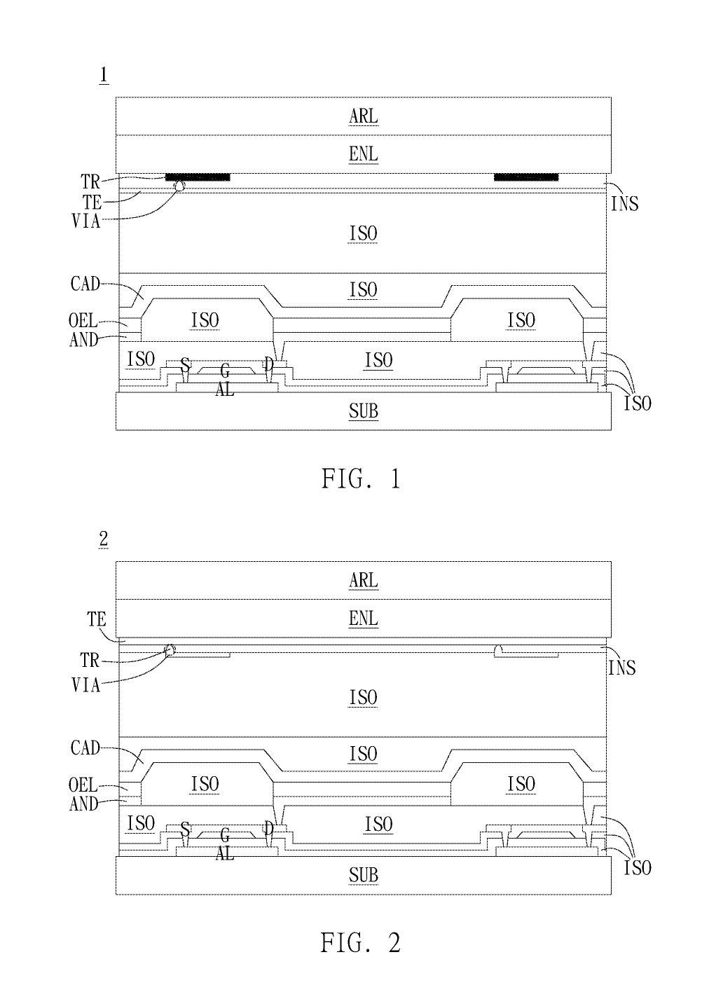

Next, please refer to FIG. 2. FIG. 2 illustrates a schematic diagram of the laminated structure of the in-cell touch panel in the second embodiment.

It should be noticed that, in the laminated structure 2 of this embodiment, the second conductive layer TE is disposed on the lower surface of the encapsulation layer ENL and used as the touch sensing electrodes of the in-cell touch panel. The first conductive layer TR is disposed under the second conductive layer TE and used as the touch sensing electrode traces of the in-cell touch panel. The first conductive layer TR and the second conductive layer TE are electrically insulated through the insulation layer INS disposed between them. The first conductive layer TR and the second conductive layer TE are coupled through the via VIA formed in the insulation layer INS.

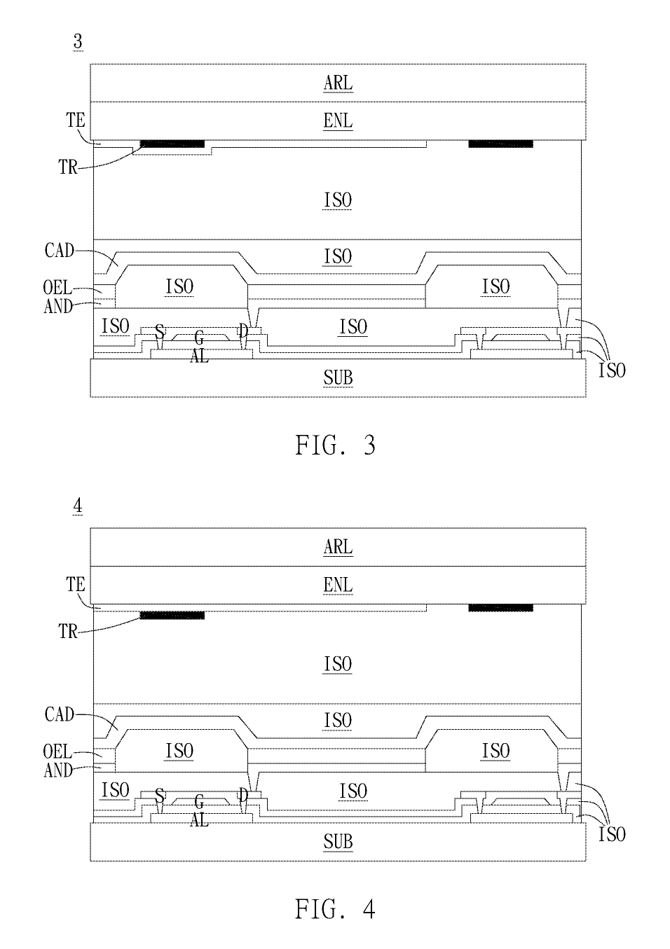

Please refer to FIG. 3. FIG. 3 illustrates a schematic diagram of the laminated structure of the in-cell touch panel in the third embodiment.

It should be noticed that, in the laminated structure 3 of this embodiment, the first conductive layer TR is disposed on the lower surface of the encapsulation layer ENL and used as the touch sensing electrode traces of the in-cell touch panel. As shown in the left part of FIG. 3, the second conductive layer TE used as touch sensing electrodes of the in-cell touch panel can cover the first conductive layer TR and coupled to the first conductive layer TR in a directly contacting way; as shown in the right part of FIG. 3, the second conductive layer TE used as touch sensing electrodes of the in-cell touch panel can be electrically insulated with the first conductive layer TR in a separating way.

Please refer to FIG. 4. FIG. 4 illustrates a schematic diagram of the laminated structure of the in-cell touch panel in the fourth embodiment.

It should be noticed that, in the laminated structure 4 of this embodiment, the second conductive layer TE is disposed on the lower surface of the encapsulation layer ENL and used as the touch sensing electrodes of the in-cell touch panel. As shown in the left part of FIG. 4, the first conductive layer TR used as touch sensing electrode traces of the in-cell touch panel can cover the second conductive layer TE and coupled to the second conductive layer TE in a directly contacting way; as shown in the right part of FIG. 4, the second conductive layer TE can be electrically insulated with the first conductive layer TR in a separating way.

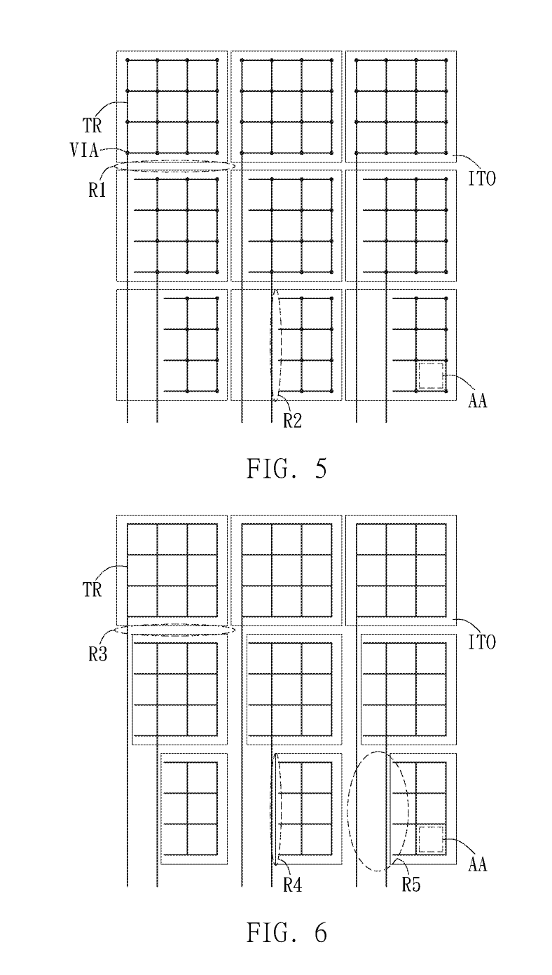

Then, please refer to FIG. 5 and FIG. 6. FIG. 5 and FIG. 6 illustrate different layout of traces in the in-cell touch panel of the invention respectively. Wherein, the layout of traces shown in FIG. 5 can correspond to the laminated structure 1 of FIG. 1 and the laminated structure 2 of FIG. 2; the layout of traces shown in FIG. 6 can correspond to the laminated structure 3 of FIG. 3 and the laminated structure 4 of FIG. 4.

As shown in FIG. 5, different touch sensing electrode traces formed by the first conductive layer TR are coupled to different touch sensing electrodes formed by the transparent conductive film ITO (e.g., the second conductive layer TE) through the via VIA. The different touch sensing electrodes formed by the transparent conductive film ITO are separated from each other and the different touch sensing electrode traces formed by the first conductive layer TR are also separated from each other. It should be noticed that the same touch sensing electrode can be coupled to different touch sensing electrode traces through different vias VIA respectively to reduce resistance, but not limited to this.

For example, as shown in the region R1 of FIG. 5, different touch sensing electrodes are separated from each other and different touch sensing electrode traces are also separated from each other; as shown in the region R2 of FIG. 5, different touch sensing electrode traces are also separated from each other.

As shown in FIG. 6, different touch sensing electrode traces formed by the first conductive layer TR are coupled to different touch sensing electrodes formed by the transparent conductive film ITO (e.g., the second conductive layer TE) in a directly contacting way. The different touch sensing electrodes formed by the transparent conductive film ITO are separated from each other and the different touch sensing electrode traces formed by the first conductive layer TR are also separated from each other. It should be noticed that different touch sensing electrode traces can be disposed in the same touch sensing electrode at the same time to reduce resistance, but not limited to this. In addition, a touch sensing electrode will not overlap the trace of another touch sensing electrode. That is to say, a touch sensing electrode will be separated from the trace of another touch sensing electrode.

For example, as shown in the region R3 of FIG. 6, different touch sensing electrodes are separated from each other and different touch sensing electrode traces are also separated from each other; as shown in the region R4 of FIG. 6, different touch sensing electrode traces are also separated from each other; as shown in the region R5 of FIG. 6, a touch sensing electrode is separated from the trace of another touch sensing electrode.

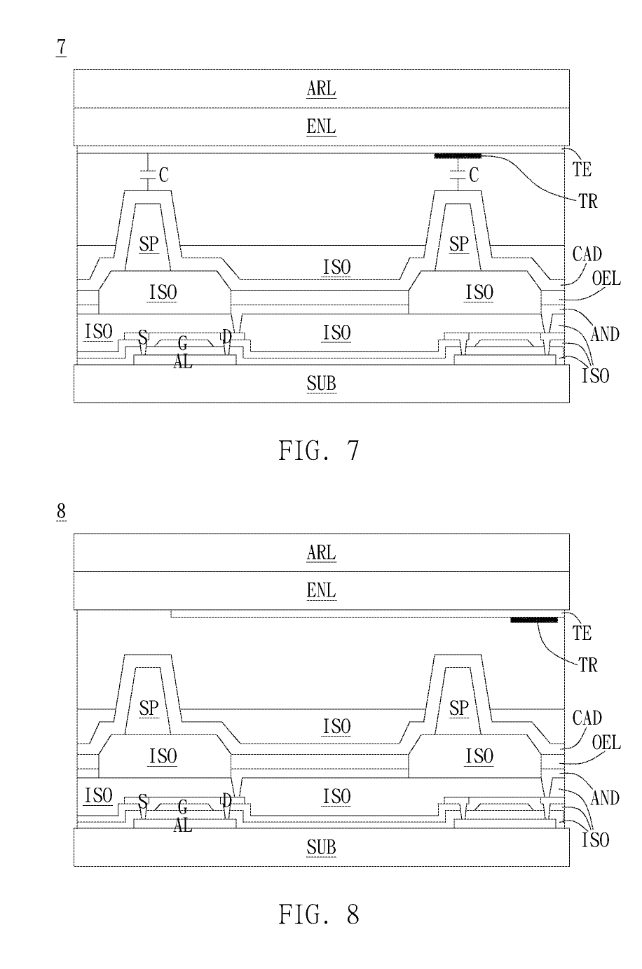

Please refer to FIG. 7. FIG. 7 illustrates a schematic diagram of the laminated structure of the in-cell touch panel in the fifth embodiment of the invention.

It should be noticed that the laminated structure 7 of this embodiment further includes a spacer SP. The spacer SP is formed above the organic light emitting OEL and the cathode layer CAD is formed on the spacer SP and the organic light emitting OEL. Since the spacer SP has a certain height and the second conductive layer TE used as touch sensing electrode is formed on the lower surface of the encapsulation layer ENL, the cathode layer CAD formed on the spacer SP will be raised and closer to the second conductive layer TE.

As shown in the right part of FIG. 7, when the first conductive layer TR used as touch sensing electrode traces is coupled to the second conductive layer TE in a directly contacting way and the position of the first conductive layer TR corresponds to the spacer SP, the distance between the cathode layer CAD formed on the spacer SP and the first conductive layer TR will become smaller, the RC loading of touch sensing will become larger and noise interference between touch sensing and display driving will also become more serious; therefore, as shown in the left part of FIG. 7, the first conductive layer TR disposed above the spacer SP in the left part of FIG. 7 can be removed to eliminate the parasitic capacitance generated between the first conductive layer TR and the cathode layer CAD above the spacer SP in the prior art, so that the RC loading of the in-cell touch panel can be effectively reduced to enhance its touch efficiency. In fact, the first conductive layer TR disposed above the spacer SP in the right part of FIG. 7 can be also removed to achieve better parasitic capacitance reducing effect, but not limited to this.

Please refer to FIG. 8. FIG. 8 illustrates a schematic diagram of the laminated structure of the in-cell touch panel in the sixth embodiment of the invention.

As shown in the right part of FIG. 8, the first conductive layer TR used as touch sensing electrode traces can bypass the spacer SP and not disposed above the spacer SP to reduce the RC loading of touch sensing; as shown in the left part of FIG. 8, not only the first conductive layer TR is not disposed above the spacer SP, but also the second conductive layer TE disposed above the spacer SP can be removed to achieve better parasitic capacitance reducing effect and effectively reduce the RC loading of touch sensing and the noise interference between touch sensing and display driving.

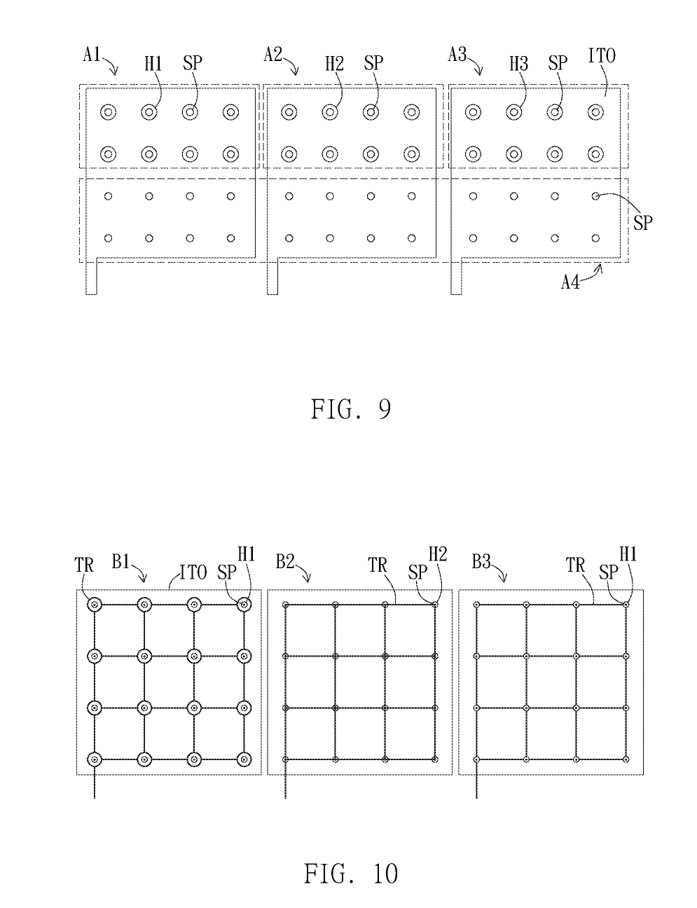

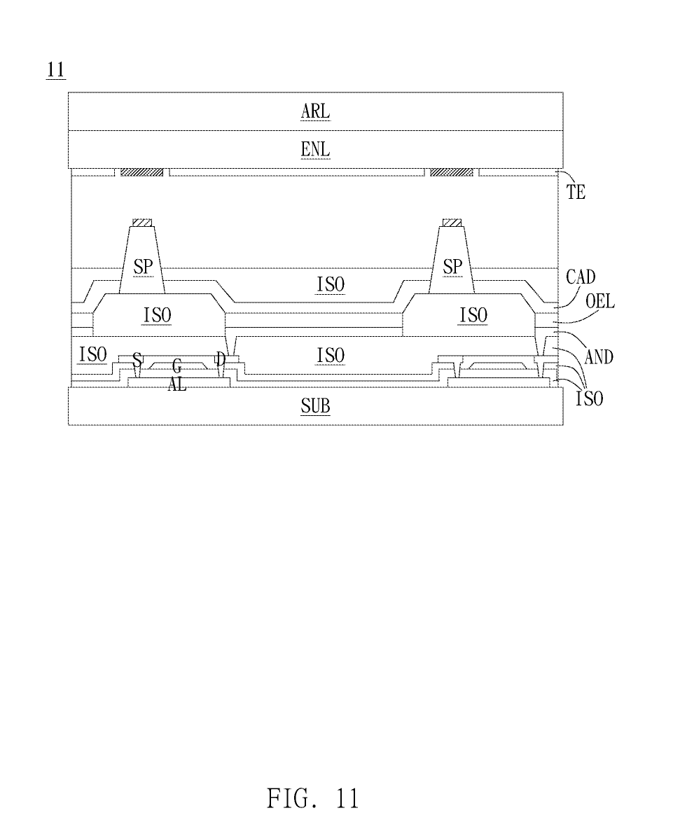

Then, please refer to FIG. 9 and FIG. 10. FIG. 9 and FIG. 10 illustrate different layout of traces in the in-cell touch panel of the invention respectively.

As shown in FIG. 9, in the area A1, the cathode layer CAD overlapping the spacer SP can be removed to leave the hole H1; in the area A2, the second conductive layer TE (e.g., the transparent conductive layer ITO) overlapping the spacer SP can be removed to leave the hole H2; in the area A3, the cathode layer CAD and the second conductive layer TE (e.g., the transparent conductive layer ITO) overlapping the spacer SP can be both removed to leave the hole H3; in the area A4, a part of the cathode layer CAD and the second conductive layer TE (e.g., the transparent conductive layer ITO) overlapping the spacer SP can be also maintained.

As shown in FIG. 10, in the area B1, the second conductive layer TE (e.g., the transparent conductive layer ITO) overlapping the spacer SP can be removed to leave the hole H1 and the first conductive layer TR used as touch sensing electrode traces will bypass the spacer SP; in the area B2, the second conductive layer TE (e.g., the transparent conductive layer ITO) overlapping the spacer SP can be removed to leave the hole H2 and the first conductive layer TR used as touch sensing electrode traces will not bypass the spacer SP; in the area B3, the second conductive layer TE (e.g., the transparent conductive layer ITO) and the first conductive layer TR overlapping the spacer SP can be both removed to leave the hole H1.

Except the above-mentioned embodiments, in order to keep the visual uniformity of the in-cell touch panel of the invention, as shown in FIG. 11, instead of completely removing the second conductive layer TE and the cathode layer CAD disposed above the spacer SP and overlapped by the spacer SP, the second conductive layer TE disposed above the spacer SP and overlapped by the spacer SP (e.g., the second conductive layer TE indicated by slash lines) can be separated from the other second conductive layer TE used as touch sensing electrodes and maintained in a floating state and the cathode layer CAD disposed above the spacer SP and overlapped by the spacer SP (e.g., the cathode layer CAD indicated by slash lines) can be separated from the other cathode layer CAD and maintained in the floating state, but not limited to this.

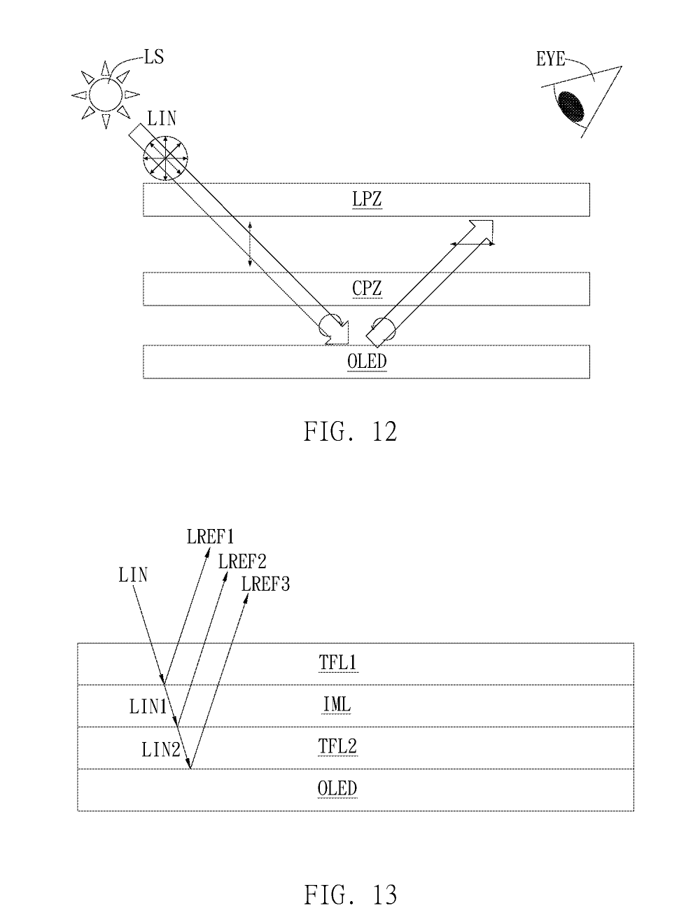

Then, please refer to FIG. 12. FIG. 12 illustrates a schematic diagram of the anti-reflection layer ARL being a combination of linear polarizer LPZ and circular polarizer CPZ.

As shown in FIG. 12, the linear polarizer LPZ is disposed above the circular polarizer CPZ and the circular polarizer CPZ is disposed above the organic light emitting display layer OLED. When the incident light LIN emitted by the external light source LS is emitted to the linear polarizer LPZ, only a linearly polarized light along a specific direction (e.g., the vertical direction) in the incident light LIN will penetrate. When the linearly polarized light is emitted downward to the circular polarizer CPZ, it will be converted into circular polarized light rotating clockwise (or counterclockwise) and then reflected by the organic light emitting display layer OLED to be a reflected light LREF and converted into circular polarized light rotating counterclockwise (or clockwise). When the circular polarized light rotating counterclockwise (or clockwise) is emitted to the circular polarizer CPZ, it will be converted into another linearly polarized light along another specific direction (e.g., the horizontal direction) vertical to the specific direction of the incident linearly polarized light, and then the another linearly polarized light will be received by the linear polarizer LPZ and not emitted to the eye EYE of the user. By doing so, the anti-reflection layer ARL including the combination of linear polarizer LPZ and circular polarizer CPZ can effectively eliminate the reflected light.

Please also refer to FIG. 13. FIG. 13 illustrates a schematic diagram of the anti-reflection layer ARL having a multilayer film structure forming destructive interference to ambient light.

As shown in FIG. 13, at least two transflective layers TFL1˜TFL2 are formed above the organic light emitting display layer OLED and an intermediate layer IML is disposed between the transflective layers TFL1˜TFL2. When the incident light LIN emitted by the external light source LS is emitted to the interface between the transflective layer TFL1 and the intermediate layer IML, a part of the incident light LIN will penetrate to form a penetrating light LIN1 and another part of the incident light LIN will be reflected to form a reflected light LREF1 emitted to outside. When the penetrating light LIN1 is emitted to the interface between the intermediate layer IML and the transflective layer TFL2, a part of the penetrating light LIN1 will penetrate to form a penetrating light LIN2 and another part of the penetrating light LIN1 will be reflected to form a reflected light LREF2 emitted to outside. When the penetrating light LIN2 is emitted to the interface between the transflective layer TFL2 and the organic light emitting display layer OLED, the penetrating light LIN2 will be reflected to form a reflected light LREF3 emitted to outside.

Therefore, the thickness and the dielectric constant of the transflective layers TFL1˜TFL2 and the intermediate layer IML in the invention can be suitably designed to generate 1/2 phase difference between the different reflected lights LREF1˜LREF3 respectively to effectively eliminate the reflected light.

Compared to the prior art, the in-cell touch panel of the invention has the following advantages and effects:

(1) The designs of touch sensing electrodes and their traces are simple.

(2) The original aspect ratio of the in-cell touch panel is not affected by the layout of the invention.

(3) The RC loading of the touch sensing electrodes can be effectively reduced.

(4) The noise interference between touching and displaying can be effectively reduced.

(5) The module thickness of the AMOLED touch panel can be effectively reduced.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An in-cell touch panel, comprising:
a plurality of pixels, a laminated structure of each pixel comprising:
a substrate;
an encapsulation layer disposed opposite to the substrate;
an organic emissive layer formed between the substrate;
a first conductive layer formed between the organic emissive layer and the encapsulation layer; and
a second conductive layer formed between the organic emissive layer and the encapsulation layer.

2. The in-cell touch panel of claim 1, wherein the in-cell touch panel is an in-cell self-capacitive touch panel or an in-cell mutual-capacitive touch panel.

3. The in-cell touch panel of claim 1, wherein the first conductive layer is used as touch electrode traces and the second conductive layer is used as touch electrodes.

4. The in-cell touch panel of claim 3, wherein the first conductive layer and the second conductive layer are coupled.

5. The in-cell touch panel of claim 4, wherein the laminated structure further comprises:
an insulation layer disposed between the first conductive layer and the second conductive layer, wherein the first conductive layer and the second conductive layer are coupled through a via formed in the insulation layer.

6. The in-cell touch panel of claim 4, wherein the first conductive layer and the second conductive layer are coupled in a directly contacting way.

7. The in-cell touch panel of claim 3, wherein the first conductive layer and the second conductive layer are electrically insulated.

8. The in-cell touch panel of claim 3, wherein the first conductive layer is disposed between the second conductive layer and the encapsulation layer.

9. The in-cell touch panel of claim 3, wherein the second conductive layer is disposed between the first conductive layer and the encapsulation layer.

10. The in-cell touch panel of claim 1, wherein the second conductive layer is formed by transparent conductive material.

11. The in-cell touch panel of claim 1, wherein the laminated structure further comprises:
a third conductive layer formed on the organic emissive layer and used as an anode or a cathode of the organic emissive layer.

12. The in-cell touch panel of claim 1, wherein the laminated structure further comprises:
a spacer formed on the organic emissive layer; and
a third conductive layer formed on the spacer and the organic emissive layer and used as an anode or a cathode of the organic emissive layer.

13. The in-cell touch panel of claim 12, wherein at least a part of the second conductive layer used as touch electrode is not formed above the spacer.

14. The in-cell touch panel of claim 12, wherein at least a part of the first conductive layer used as touch electrode trace is not formed above the spacer.

15. The in-cell touch panel of claim 12, wherein a part of the third conductive layer formed above the spacer, separated from another part of the third conductive layer used as the anode or the cathode of the organic emissive layer, is maintained in a floating state.

16. The in-cell touch panel of claim 1, wherein the laminated structure further comprises:
an anti-reflection layer, formed above the encapsulation layer, for eliminating reflected light.

17. The in-cell touch panel of claim 16, wherein the anti-reflection layer is a combination of linear polarizer and circular polarizer.

18. The in-cell touch panel of claim 16, wherein the anti-reflection layer has a multilayer film structure forming destructive interference to ambient light.

19. The in-cell touch panel of claim 1, wherein the first conductive layer is formed in mesh type or along a single direction in an active area of the in-cell touch panel.

20. The in-cell touch panel of claim 1, wherein when the organic emissive layer emits a white light, the in-cell touch panel further comprises:
a color filter layer, formed above the organic emissive layer, for filtering the white light.
